(19) United States
(12) Patent Application Publication
(10) Pub. No.: US 2025/0309851 A1
(43) Pub. Date: Oct. 2, 2025

(54) FILTER MODULE AND ANTENNA MODULE INCLUDING THE SAME

(71) Applicant: LG INNOTEK CO., LTD., Seoul (KR)

(72) Inventors: Yu Seon KIM, Seoul (KR); Il Hee PARK, Seoul (KR)

(73) Assignee: LG INNOTEK CO., LTD., Seoul (KR)

(21) Appl. No.: 18/864,261

(22) PCT Filed: Jul. 7, 2023
(86) PCT No.: PCT/US2023/027143

§ 371 Date: Nov. 8, 2024

(30) Foreign Application Priority Data
May 11, 2022 (KR) 10-2022-0057776
May 10, 2023 (KR) 10-2023-0060576

(51) Int. Cl. H03H 7/01; H01Q 9/04; H03H 1/00

(52) U.S. Cl. CPC H03H 7/0115; H01Q 9/0414; H03H 1/00; H03H 2001/0021

(57) ABSTRACT

A filter module is disclosed. The filter module includes a first ground layer, a second ground layer disposed so as to be spaced apart from the first ground layer, a first conductive pattern layer disposed between the first ground layer and the second ground layer, a second conductive pattern layer disposed on one side of the first ground layer or the second ground layer, and a via interconnecting at least two of the first ground layer, the second ground layer, the first conductive pattern layer, and the second conductive pattern layer.

### TECHNICAL FIELD

Embodiments relate to an antenna module including a filter module or Wi-Fi and Bluetooth antennas and to a high-frequency module including the same.

### BACKGROUND ART

Filters configured to filter a signal in a desired frequency band may be applied to various devices or fields including antennas. Such a band-pass filter requires an inductor and a capacitor.

If a band-pass filter is implemented using an inductor and a capacitor, which are lumped elements, there occur various problems in that insertion loss increases, a signal distortion rate increases, and the thickness or size thereof increases. Therefore, research with the goal of solving these problems is underway.

A Bluetooth module is a device that includes a series of chips and antennas and performs communication in a band of approximately 2.4 to 2.5 GHz at a distance of about 10 to 100 meters according to a Bluetooth wireless interface standard.

A wireless fidelity (Wi-Fi) module is a device that performs short-range communication in a band of approximately 2.4 to 2.5 GHz or at a band of approximately 5 GHz. The Wi-Fi module enables wireless Internet using a radio wave or infrared transmission scheme in a place where a wireless access device (or an access point (AP)) is installed, or performs communication with another Wi-Fi module through direct connection thereto (Wi-Fi Direct) in a P2P network.

Conventionally, Bluetooth and Wi-Fi modules are implemented as independent (individual) modules and are mounted in electronic products. Therefore, in the case in which both a Bluetooth module and a Wi-Fi module need to be mounted in a certain electronic product, various problems may arise in terms of reduction in the size of the product or system stability.

In detail, both the Bluetooth module and the Wi-Fi module are devices that perform communication using RF signals. Therefore, some elements may be included in common in the Bluetooth module and the Wi-Fi module. However, when the Bluetooth module and the Wi-Fi module are implemented as independent modules, such common elements may be individually provided and used, which may make it difficult to reduce the size of a product and may cause waste of electronic elements and system instability.

Further, the Bluetooth module uses a channel overlapping the channel of the Wi-Fi module, but does not use a band of 5 to 6 GHz. Therefore, an antenna for Bluetooth requires a filter capable of filtering a band of 5 to 6 GHz. However, when a circuit is configured using a passive element, the size thereof may increase, and the price competitiveness thereof may decrease.

### DISCLOSURE

### Technical Problem

Embodiments provide a filter module having improved performance and structure.

Embodiments provide a novel antenna module capable of solving the above problems.

Embodiments provide an antenna module including a filter for Bluetooth embedded in a board without using a passive element.

Embodiments provide an antenna module including a low-pass filter embedded in a board and connected to an antenna for Bluetooth without using a passive element.

### Technical Solution

A filter module according to an embodiment may include a first ground layer, a second ground layer disposed so as to be spaced apart from the first ground layer, a first conductive pattern layer disposed between the first ground layer and the second ground layer, a second conductive pattern layer disposed on one side of the first ground layer or the second ground layer, and a via interconnecting at least two of the first ground layer, the second ground layer, the first conductive pattern layer, and the second conductive pattern layer.

In an example, the first conductive pattern layer may include a capacitance pattern formed to include a capacitance while facing at least one of the first ground layer or the second ground layer.

In an example, the first conductive pattern layer may include a first inductance pattern formed to include an inductance.

In an example, the second conductive pattern layer may include a second inductance pattern formed to include an inductance.

In an example, the inductance pattern may have a smaller width than the capacitance pattern.

In an example, the second conductive pattern layer may include a first opening formed therein to allow the second inductance pattern to be disposed therein, and the first ground layer may include a second opening formed therein so as to vertically overlap the first opening.

In an example, each of the first inductance pattern and the second inductance pattern may include an inductance pattern having a planar shape bent at least once in a horizontal direction, and the maximum number of bends of the first inductance pattern in the horizontal direction may be greater than the maximum number of bends of the second inductance pattern.

In an example, the capacitance pattern may include a second capacitor pattern forming a second capacitor, a first capacitor pattern disposed so as to be spaced apart from one side of the second capacitor pattern to form a first capacitor, and a third capacitor pattern disposed so as to be spaced apart from the opposite side of the second capacitor pattern to form a third capacitor.

In an example, the second capacitor pattern may include a first stub, a second stub disposed on one side of the first stub, and a third stub disposed on the opposite side of the first stub.

In an example, the first inductance pattern may include a first inductor pattern disposed so as to interconnect a first via and a second via to form a first inductor, a second inductor pattern disposed so as to interconnect the first via and the first capacitor pattern to form a second inductor, a fifth inductor pattern disposed so as to interconnect a third via and the third capacitor pattern to form a fifth inductor, and a sixth inductor pattern disposed so as to interconnect the third via and a fourth via to form a sixth inductor.

In an example, the second inductance pattern may include a third inductor pattern disposed so as to interconnect the first via and a fifth via and interconnect the fifth via and a sixth via to form a third inductor and a fourth inductor pattern disposed so as to interconnect the sixth via and the third via to form a fourth inductor. The sixth via may be connected to the second capacitor pattern.

In an example, at least one of the first to sixth inductor patterns may have a line width of 250 μm or less.

In an example, at least one of the first capacitor pattern or the third capacitor pattern may have a line width of 300 μm or greater.

In an example, at least one of the first to sixth inductor patterns may have a length equal to or less than one-eighth of a wavelength at a fundamental frequency.

A filter module according to another embodiment may include a second ground layer, a first conductive pattern layer stacked on the second ground layer and including a pattern implementing an inductor and a capacitor, a first ground layer stacked on the first conductive pattern layer, a second conductive pattern layer stacked on the first ground layer and including a transmission line including a pattern implementing an inductor, and a via interconnecting the inductor and the capacitor of the first conductive pattern layer and the inductor of the second conductive pattern layer in a vertical direction.

An antenna module according to an embodiment of the present disclosure may include a board to which a first antenna is coupled, a low-pass filter unit embedded in a portion of the board, and a first transmission line interconnecting the first antenna and the low-pass filter unit. The low-pass filter unit may include first to fourth conductive layers and first to third dielectric layers respectively disposed between the first to fourth conductive layers. The first conductive layer may include a first pattern including a first via, a second pattern connected between one end of the first pattern and a second via, and a third pattern connected to a third via. The second conductive layer may include a ground pattern spaced apart from the first to third vias formed therein by predetermined gaps. The third conductive layer may include a fourth pattern facing the first pattern and a fifth pattern spaced apart from the fourth pattern and facing the second via and the third pattern. The fourth conductive layer may include a sixth pattern connected between the second via and a ground via formed therein and a seventh pattern connected between the second via and the third via. The first pattern and the third pattern of the first conductive layer, the fourth pattern and the fifth pattern of the third conductive layer, and the first and second dielectric layers may form first and second capacitors. The second pattern, the sixth pattern, and the seventh pattern may have a line shape and may form first to third inductors.

According to an embodiment of the present disclosure, the first pattern and the third pattern of the first conductive layer and the fourth pattern and the fifth pattern of the third conductive layer may have a polygonal plate shape.

According to an embodiment of the present disclosure, the area of the upper surface of the fifth pattern may be smaller than the area of the upper surface of the third pattern, and may be larger than the area of the upper surface of the first pattern.

According to an embodiment of the present disclosure, the area of the upper surface of the third pattern may be smaller than the area of the upper surface of the first pattern.

According to an embodiment of the present disclosure, the first conductive layer may include a first input/output pattern connected to the other end of the first pattern and the first transmission line and a second input/output pattern connected to the second pattern and a second transmission line disposed on the opposite side of the low-pass filter unit.

According to an embodiment of the present disclosure, the sixth pattern may have a greater length than the second pattern.

According to an embodiment of the present disclosure, the number of bends of the sixth pattern may be greater than that of the second and seventh patterns.

According to an embodiment of the present disclosure, the first capacitor may include a first capacitance, which is generated by the first dielectric layer between the first pattern of the first conductive layer and a first circular pattern connected to the first via of the second conductive layer, and a second capacitance, which is generated by the second dielectric layer between the first circular pattern and the fourth pattern.

According to an embodiment of the present disclosure, the second capacitor may be connected to the fifth pattern, a third circular pattern connected to the third via of the second conductive layer, and the third pattern of the first conductive layer via the third via connected to the seventh pattern of the fourth conductive layer. The second capacitor may include a third capacitance, which is generated between the third circular pattern and the fourth pattern, and a fourth capacitance, which is generated by the first dielectric layer between the fifth pattern and the third circular pattern.

According to an embodiment of the present disclosure, the second capacitor may include a fifth capacitance, which is generated by the first dielectric layer between the first via of the first conductive layer and a second circular pattern connected to the second via of the second conductive layer, and a sixth capacitance, which is generated by the second dielectric layer between the second circular pattern and a fourth circular pattern connected to the second via of the third conductive layer.

According to an embodiment of the present disclosure, the third and fifth capacitances may be connected in parallel to each other, and the fourth and sixth capacitances may be connected in parallel to each other.

According to an embodiment of the present disclosure, the antenna module may include a Wi-Fi module connected to the low-pass filter unit via the second transmission line and a second antenna connected to the Wi-Fi module. The first antenna may be a Bluetooth antenna, and the second antenna may be a Wi-Fi antenna.

According to an embodiment of the present disclosure, the low-pass filter unit may pass a band of 2402 to 2480 MHz, and may filter a band of 5 to 6 GHz.

A high-frequency module according to an embodiment of the present disclosure may include a low-pass filter unit configured such that a first input/output pattern is electrically connected to a Bluetooth antenna and a second input/output pattern is electrically connected to a Wi-Fi module. The low-pass filter unit may include first to fourth conductive layers, dielectric layers respectively disposed between the first to fourth conductive layers, and a plurality of vias vertically formed through the first to fourth conductive layers and the dielectric layers and selectively interconnecting patterns of different conductive layers. Patterns on one side of each of the first to third conductive layers and the dielectric layers disposed between the first to third conductive layers may face each other and may form a first capacitor connected in parallel to a first branch node connected to the first input/output pattern. A first line pattern of the first conductive layer may form a first inductor connected to the first branch node in series. A second line pattern of the fourth conductive layer may form a second inductor connected in parallel to a third branch node connected to the other end of the first inductor. A third line pattern of the fourth conductive layer may form a third inductor connected in parallel to a second branch node connected between the second input/output pattern and the third branch node. Patterns on the other side of each of the first to third conductive layers and the dielectric layers disposed between the first to third conductive layers may face each other and may form a second capacitor connected to the third inductor in series. The other end of the first capacitor, the other end of the second inductor, and the other end of the second capacitor may be connected to a ground pattern.

According to an embodiment of the present disclosure, the low-pass filter unit may pass a band of 2402 to 2480 MHz, and may filter a band of 5 to 6 GHz.

According to an embodiment of the present disclosure, the first to third branch nodes may be respectively formed by the vias disposed in the low-pass filter unit.

### Advantageous Effects

As is apparent from the above description, according to a filter module according to the embodiment, a sufficient length of an inductor may be secured in a limited space, and thus, the inductor may be designed to include a desired inductance. In addition, a f frequency component may be improved, and insertion loss may be reduced. Accordingly, the efficiency of an may be antenna improved, and consequently, a transmission distance and a transmission rate may increase. In addition, delay may be improved, and thus, a signal distortion rate may be reduced. In addition, the thickness of the filter module may be reduced compared to a filter module implemented using passive elements.

Further, the embodiment may reduce the size of an antenna module by embedding the filter in a board without using parts of an inductor and a capacitor. In addition, cost of manufacturing the antenna module may be reduced. In addition, it is possible to filter a band of 5 to 6 GHz by connecting the low-pass filter (LPF) embedded in the board of the antenna module to a Bluetooth antenna. In addition, insertion loss in a band of 5 to 6 GHz may be equal to or less than −3 dB.

The features, structures, effects, and the like described above in the embodiments are included in at least one embodiment of the present disclosure, but are not necessarily limited to only one embodiment. Furthermore, the features, structures, effects, and the like exemplified in the respective embodiments may be combined with other embodiments or modified by those skilled in the art. Therefore, content related to such combinations and modifications should be construed as falling within the scope of the present disclosure.

While the present disclosure has been particularly shown and described with reference to exemplary embodiments thereof, these embodiments are only proposed for illustrative purposes, and do not restrict the present disclosure, and it will be apparent to those skilled in the art that various changes in form and detail may be made without departing from the essential characteristics of the embodiments set forth herein. For example, respective configurations set forth in the embodiments may be modified and applied. Further, differences in such modifications and applications should be construed as falling within the scope of the present disclosure as defined by the appended claims.

### DESCRIPTION OF DRAWINGS

Arrangements and embodiments may be described in detail with reference to the following drawings in which like reference numerals refer to like elements and wherein:

FIG. 1 is a conceptual diagram schematically showing a filter module according to an embodiment;

FIG. 2 is a circuit diagram showing an embodiment of the filter module shown in FIG. 1;

FIGS. 3A and 3B are, respectively, a perspective view and a plan view of the second conductive pattern layer shown in FIG. 1;

FIGS. 4A and 4B are, respectively, a perspective view and a plan view of the first ground layer shown in FIG. 1;

FIGS. 5A and 5B are, respectively, a perspective view and a plan view of the first conductive pattern layer shown in FIG. 1;

FIGS. 6A and 6B are, respectively, a perspective view and a plan view of the second ground layer shown in FIG. 1;

FIG. 7 is a graph showing insertion loss of the filter module according to the embodiment at each frequency;

FIG. 8 is a graph showing inductance implemented by first and sixth inductor patterns at each frequency;

FIG. 9 is a graph showing capacitance of a second capacitor pattern at each frequency;

FIG. 10 is a graph showing insertion loss of a filter module according to a comparative example and insertion loss of the filter module according to the embodiment;

FIG. 11 is a diagram illustrating the connection structure of the filter module according to the embodiment;

FIG. 12 is a block configuration diagram of an antenna module according to an embodiment of the present disclosure;

FIG. 13 is a plan view showing a part of the antenna module shown in FIG. 12;

FIG. 14 is a perspective view of the low-pass filter unit shown in FIG. 13;

FIG. 15 is a side view of the low-pass filter unit shown in FIG. 14;

FIG. 16 is a diagram showing the circuit configuration of the low-pass filter according to the present disclosure;

FIG. 17 is an exploded perspective view of the low-pass filter unit shown in FIG. 14;

FIG. 18 is a view showing patterns of first to fourth conductive layers of the low-pass filter unit shown in FIG. 17;

FIG. 19 is a cross-sectional view taken along line A-A in the low-pass filter unit shown in FIG. 14;

FIG. 20 is a cross-sectional view taken along line B-B in the low-pass filter unit shown in FIG. 14; and

FIG. 21 is a graph showing the operational characteristics of the low-pass filter unit of the antenna module according to the embodiment of the present disclosure.

### BEST MODE

Hereinafter, exemplary embodiments of the present disclosure will be described in detail with reference to the accompanying drawings.

The technical spirit of the disclosure is not limited to the embodiments to be described, and may be implemented in various other forms, and one or more of the components may be selectively combined and substituted for use without exceeding the scope of the technical spirit of the disclosure.

In addition, terms (including technical and scientific terms) used in the embodiments of the disclosure, unless specifically defined and described explicitly, are to be interpreted as having meanings that may be generally understood by those having ordinary skill in the art to which the disclosure pertains, and meanings of terms that are commonly used, such as terms defined in a dictionary, should be interpreted in consideration of the context of the relevant technology.

Further, the terms used in the embodiments of the disclosure are for explaining the embodiments and are not intended to limit the disclosure. In this specification, the singular forms may also include plural forms unless otherwise specifically stated in a phrase, and in the case in which “at least one (or one or more) of A, B, or C” is stated, it may include one or more of all possible combinations of A, B, and C.

In addition, in describing the components of the embodiments of the disclosure, terms such as “first,” “second,” “A,” “B,” “(a),” and “(b)” can be used. Such terms are only for distinguishing one component from another component, and do not determine the nature, sequence, or procedure of the corresponding constituent elements.

In addition, when it is described that a component is “connected,” “coupled” or “joined” to another component, the description may include not only being directly “connected,” “coupled” or “joined” to the other component but also being “connected,” “coupled” or “joined” by another component between the component and the other component.

In addition, in the case of being described as being formed or disposed “above (on)” or “below (under)” another component, the description includes not only the case where the two components are in direct contact with each other, but also the case where one or more other components are formed or disposed between the two components. In addition, when expressed as “above (on)” or “below (under),” it may refer to a downward direction as well as an upward direction with respect to one element.

Hereinafter, filter modules 10 and 10A according to embodiments will be described with reference to the accompanying drawings. The filter modules 10 and 10A will be described using the Cartesian coordinate system (x-axis, y-axis, z-axis) for convenience of description, but may also be described using other coordinate systems. In the Cartesian coordinate system, the x-axis, the y-axis, and the z-axis are perpendicular to each other, but the embodiments are not limited thereto. That is, the x-axis, the y-axis, and the z-axis may intersect each other obliquely.

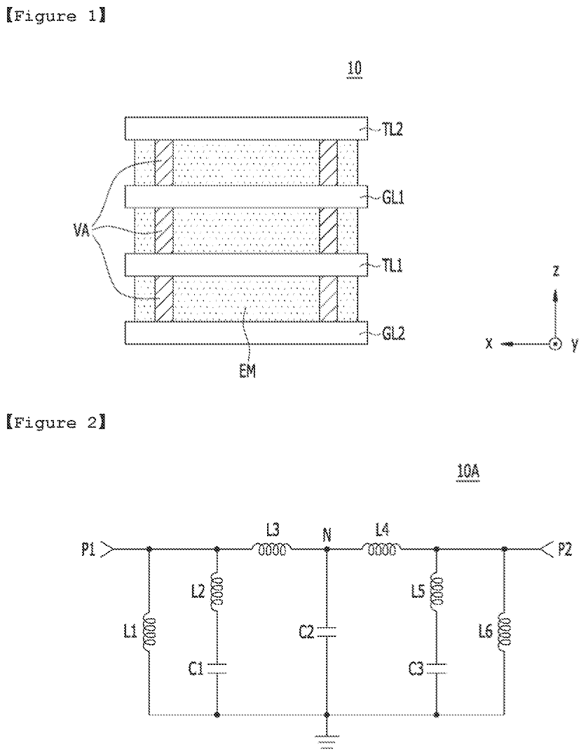

FIG. 1 is a conceptual diagram schematically showing a filter module 10 according to an embodiment.

The filter module 10 shown in FIG. 1 may include a first ground (or reference potential) layer GL1, a second ground layer GL2, a first conductive pattern layer TL1, a second conductive pattern layer TL2, and vias VA. The first ground layer GL1, the second ground layer GL2, the first conductive pattern layer TL1, and the second conductive pattern layer TL2 may be referred to as a first layer, a second layer, a third layer, and a fourth layer, respectively.

The first ground layer GL1 and the second ground layer GL2 are disposed so as to be spaced apart from each other.

The first conductive pattern layer TL1 is disposed between the first ground layer GL1 and the second ground layer GL2.

The second conductive pattern layer TL2 may be disposed on one side of the first ground layer GL1 or the second ground layer GL2. For example, as shown in FIG. 1, the second conductive pattern layer TL2 may be disposed on the first ground layer GL1.

As shown in the drawing, the filter module 10 according to an embodiment may include a second conductive pattern layer TL2, a first ground layer GL1, a first conductive pattern layer TL1, and a second ground layer GL2, which are stacked one above another in a vertical direction (e.g. the z-axis direction). That is, the second conductive pattern layer TL2 may be disposed at the highest position within the filter module 10, the second ground layer GL2 may be disposed at the lowest position within the filter module 10, and the first ground layer GL1 and the first conductive pattern layer TL1 may be disposed between the second conductive pattern layer TL2 and the second ground layer GL2 in a stacked manner.

The vias VA may be disposed between the first ground layer GL1, the second ground layer GL2, the first conductive pattern layer TL1, and the second conductive pattern layer TL2. The vias may be formed in the shape of a groove or a hole, and may serve as electrical signal connection paths between the layers.

The first conductive pattern layer TL1 includes a transmission line including a pattern implementing an inductor and a capacitor, and the second conductive pattern layer TL2 includes a transmission line including a pattern implementing an inductor. In this case, the vias VA serve to connect the inductor and capacitor of the first conductive pattern layer TL1 to the inductor of the second conductive pattern layer TL2 in the vertical direction. In addition, the vias VA may also serve to interconnect the first ground layer GL1, the second ground layer GL2, the first conductive pattern layer TL1, and the second conductive pattern layer TL2 in the vertical direction.

A filter (e.g. a band-pass filter) including various circuits may be implemented using the filter module 10 described above with reference to FIG. 1.

Hereinafter, the configuration and operation of a band-pass filter 10A according to an embodiment implemented by the filter module 10 shown in FIG. 1 will be described. However, the disclosure is not limited thereto. That is, the filter module 10 shown in FIG. 1 may also implement a filter having a configuration or role different from that of the band-pass filter 10A shown in FIG. 2.

FIG. 2 is a circuit diagram showing an embodiment 10A of the filter module 10 shown in FIG. 1.

The filter module 10A shown in FIG. 2 may include first, second, and third capacitors C1, C2, and C3 and first, second, third, fourth, fifth, and sixth inductors L1, L2, L3, L4, L5, and L6.

The first inductor L1 is connected between a first port P1 and a ground, and the sixth inductor L6 is connected between a second port P2 and the ground.

The second inductor L2 and the first capacitor C1 may be connected to each other in series between the first port P1 and the ground, and the fifth inductor L5 and the third capacitor C3 may be connected to each other in series between the second port P2 and the ground.

The third inductor L3 and the fourth inductor L4 may be connected to each other in series between the first port P1 and the second port P2. The second capacitor C2 may be connected between a node N between the third inductor L3 and the fourth inductor L4 and the ground.

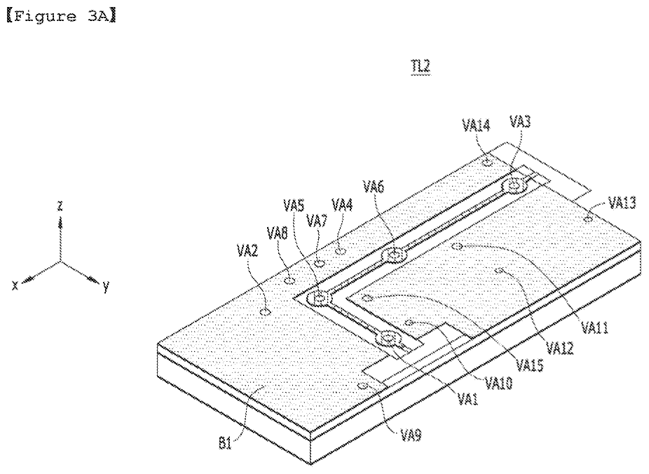

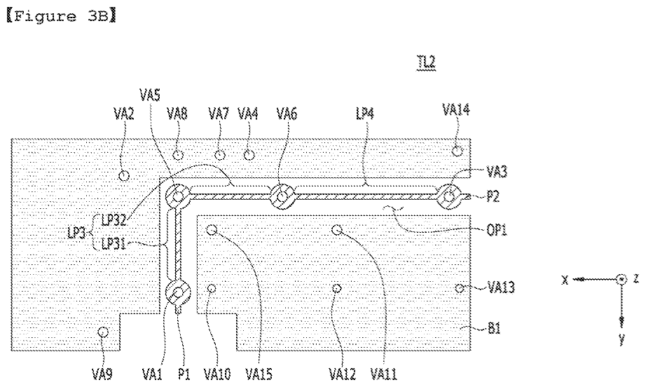

Hereinafter, the configuration of a specific embodiment of the filter module 10 shown in FIG. 1 implementing the band-pass filter shown in FIG. 2 will be described with reference to FIGS. 3A to 6B. However, the disclosure is not limited thereto. Further, the filter module 10 according to the embodiment will be described as being configured such that the second ground layer GL2, the first conductive pattern layer TL1, the first ground layer GL1, and the second conductive pattern layer TL2 are sequentially stacked one above another from below to above, as shown in FIG. 1. However, the disclosure is not limited thereto.

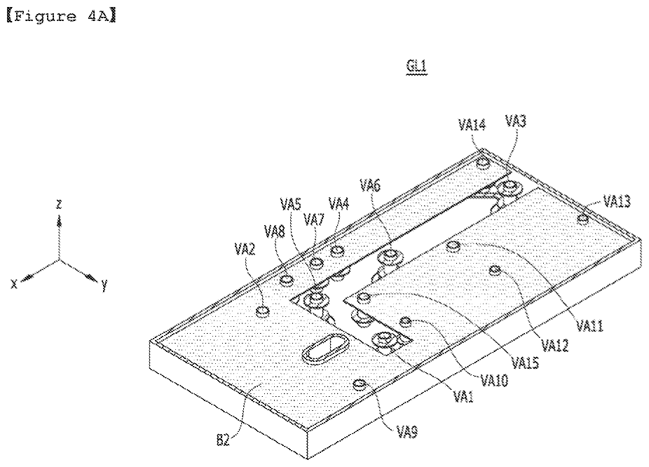

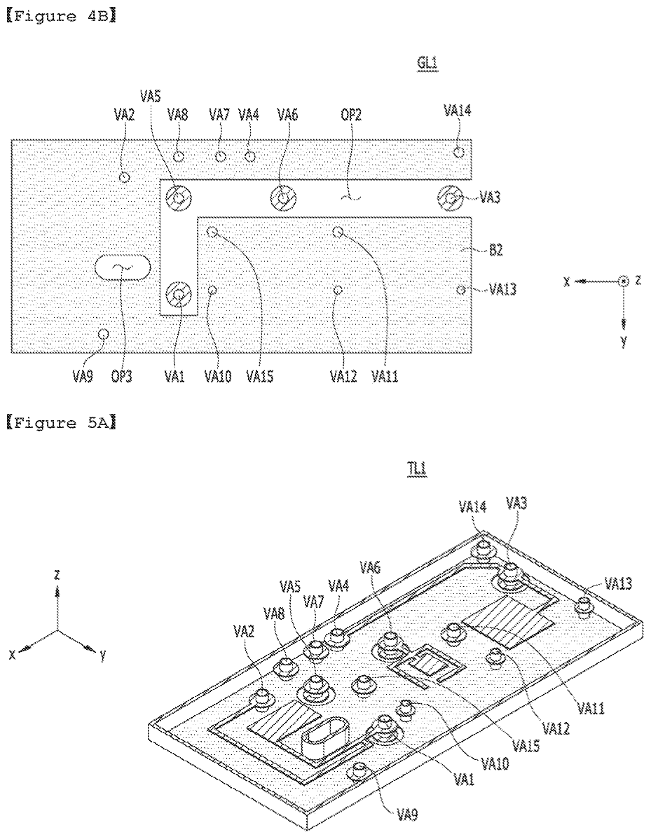

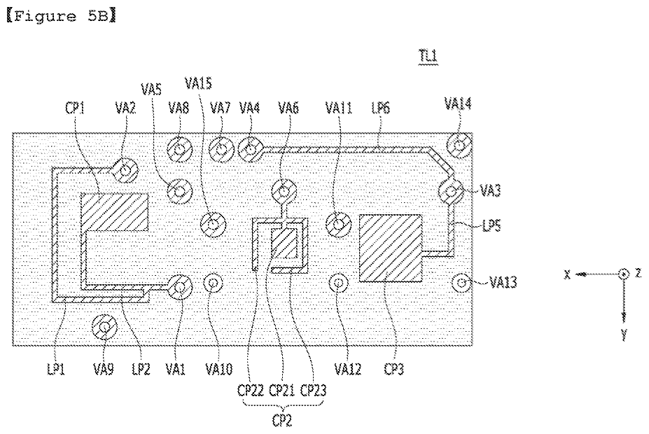

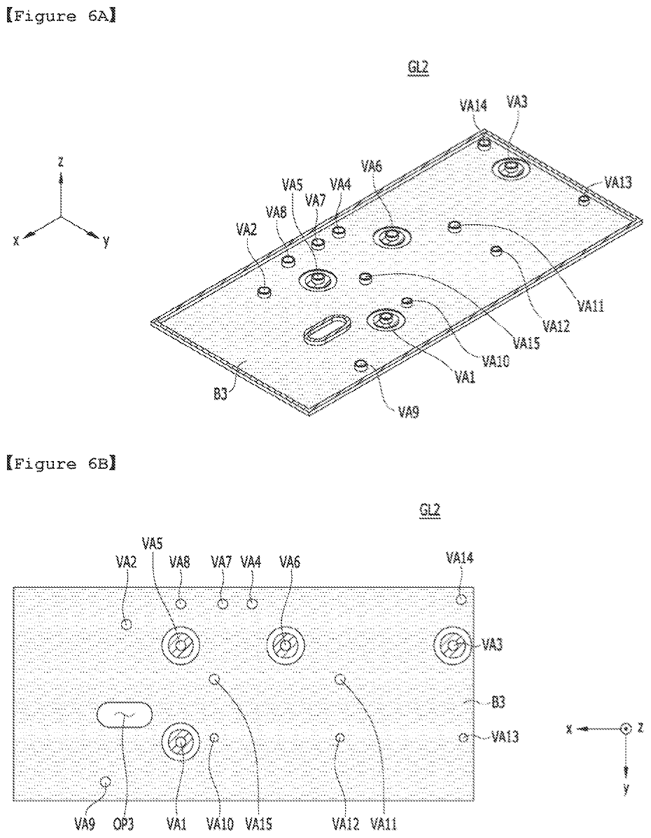

FIGS. 3A and 3B are, respectively, a perspective view and a plan view of the second conductive pattern layer TL2 shown in FIG. 1. FIGS. 4A and 4B are, respectively, a perspective view and a plan view of the first ground layer GL1 shown in FIG. 1. FIGS. 5A and 5B are, respectively, a perspective view and a plan view of the first conductive pattern layer TL1 shown in FIG. 1. FIGS. 6A and 6B are, respectively, a perspective view and a plan view of the second ground layer GL2 shown in FIG. 1.

Referring to FIGS. 3A and 3B, the second conductive pattern layer TL2 includes a first body B1, which includes a first opening OP1, and a second inductance pattern. The first body B1 may be connected to the ground. In this specification, the opening may be an area in which a conductive material is not disposed by etching or the like, and the body may be a ground area, which is a relatively broad area.

The second inductance pattern may be disposed in the first opening OP1 and may be formed to include an inductance. That is, the second conductive pattern layer TL2 may form the inductance of each of the third and fourth inductors L3 and L4 shown in FIG. 2 using a transmission line. In this case, if the width of the transmission line is too large, the total length of the lines of the third and fourth inductors L3 and L4 may increase, and thus the size of a product may increase. Therefore, the line is made to have a small width. The line width will be described in detail later.

For example, the second inductance pattern may include a third inductor pattern LP3 and a fourth inductor pattern LP4.

The third inductor pattern LP3 may include a 3-1^{st} inductor pattern LP31, which is disposed so as to interconnect a first via VA1 and a fifth via VA5 to form a 3-1^{st} inductor, and a 3-2^{nd} inductor pattern LP32, which is disposed so as to interconnect the fifth via VA5 and a sixth via VA6 to form a 3-2^{nd} inductor. A third inductor constituted by the 3-1^{st} inductor and the 3-2^{nd} inductor corresponds to the third inductor L3 shown in FIG. 2.

The fourth inductor pattern LP4 may be disposed so as to interconnect the sixth via VA6 and a third via VA3 to form a fourth inductor. The fourth inductor formed by the fourth inductor pattern LP4 corresponds to the fourth inductor L4 shown in FIG. 2.

The first, fifth, sixth, and third vias VA1, VA5, VA6, and VA3 and the third and fourth inductor patterns LP3 and LP4, which are disposed in the first opening OP1, are spaced apart from the first body B1.

The first and second ports P1 and P2 shown in FIG. 3B correspond to the first and second ports P1 and P2 shown in FIG. 2, respectively. The first port P1 may be an input port Rx, and the second port P2 may be an output port Tx. Alternatively, the first port P1 may be an output port Tx, and the second port P2 may be an input port Rx. For example, the first port P1 may be connected to an IC pad (not shown), and the second port P2 may be connected to a Bluetooth (BT) antenna (not shown). Alternatively, the first port P1 may be connected to the Bluetooth antenna, and the second port P2 may be connected to the IC pad. However, the disclosure is not limited thereto.

Referring to FIGS. 4A and 4B, the first ground layer GL1 includes a second body B2 including a second opening OP2. The second body B2 is connected to the ground or the reference potential. The second opening OP2 may be disposed so as to overlap the first opening OP1 in the z-axis direction, which is the vertical direction. Accordingly, the first, fifth, sixth, and third vias VA1, VA5, VA6, and VA3, which are disposed in the first opening OP1 and are spaced apart from the first body B1, may be disposed so as to be spaced apart from the second body B2.

If the first ground layer GL1 does not include the second opening OP2 and is shielded by ground, it may be possible to implement a pattern on the first conductive pattern layer TL1 without interference. However, the lengths of lines for implementing the third and fourth inductor patterns LP3 and LP4 may increase. For this reason, as shown in FIG. 4B, the second opening OP2 is formed in the first ground layer GL1 to implement a coplanar waveguide structure.

Referring to FIGS. 5A and 5B, the first conductive pattern layer TL1 includes a capacitance pattern and a first inductance pattern.

The capacitance pattern is formed to include a capacitance while facing at least one of the first ground layer GL1 or the second ground layer GL2. In the embodiment, the capacitance pattern is formed so as to face both the first ground layer and the second ground layer.

The first inductance pattern is formed to include an inductance.

The capacitance pattern may include a first capacitor pattern CP1, a second capacitor pattern CP2, and a third capacitor pattern CP3.

The first, second, and third capacitor patterns CP1, CP2, and CP3 form first, second, and third capacitors, respectively. In this case, the first, second, and third capacitors may correspond to the first, second, and third capacitors C1, C2, and C3 shown in FIG. 2, respectively.

The first capacitor pattern CP1 may be disposed so as to be spaced apart from one side of the second capacitor pattern CP2, and the third capacitor pattern CP3 may be disposed so as to be spaced apart from the opposite side of the second capacitor pattern CP2. Each of the first and third capacitor patterns CP1 and CP3 is illustrated as having a rectangular planar shape, but the disclosure is not limited to any specific planar shape of the pattern.

According to the embodiment, the second capacitor pattern CP2 may include a plurality of stubs. For example, the second capacitor pattern CP2 may include first, second, and third stubs CP21, CP22, and CP23. The second stub CP22 and the third stub CP23 may be disposed on both sides of the first stub CP21, with the first stub CP21 interposed therebetween. That is, the second stub CP22 may be disposed on one side of the first stub CP21, and the third stub CP23 may be disposed on the opposite side of the first stub CP21.

The sixth via VA6, which is connected between the third inductor pattern LP3 and the fourth inductor pattern LP4, may be connected to the second capacitor pattern CP2 in the vertical direction.

The first inductance pattern may include a first inductor pattern LP1, a second inductor pattern LP2, a fifth inductor pattern LP5, and a sixth inductor pattern LP6.

The first inductor pattern LP1 may be disposed so as to interconnect the first via VA1 and the second via VA2 to form a first inductor. Here, the first inductor corresponds to the first inductor L1 shown in FIG. 2.

The second inductor pattern LP2 may be disposed so as to interconnect the first via VAL and the first capacitor pattern CP1 to form a second inductor. Here, the second inductor corresponds to the second inductor L2 shown in FIG. 2. The second inductor pattern LP2 may be connected to the third inductor pattern LP3 through the first via VA1.

The fifth inductor pattern LP5 may be disposed so as to interconnect the third via VA3 and the third capacitor pattern CP3 to form a fifth inductor. Here, the fifth inductor corresponds to the fifth inductor L5 shown in FIG. 2.

The sixth inductor pattern LP6 may be disposed so as to interconnect the third via VA3 and the fourth via VA4 to form a sixth inductor. Here, the sixth inductor corresponds to the sixth inductor L6 shown in FIG. 2.

The fifth inductor pattern LP5 and the sixth inductor pattern LP6 may be connected to the fourth inductor pattern LP4 through the third via VA3.

According to the embodiment, the first or second inductance pattern may have a planar shape that is bent at least once in the horizontal direction. For example, as shown in FIG. 5B, each of the first inductor pattern LP1 and the sixth inductor pattern LP6 may have a planar shape that is bent twice in the horizontal direction, and each of the second inductor pattern LP2 and the fifth inductor pattern LP5 may have a planar shape that is bent once in the horizontal direction.

Referring to FIGS. 6A and 6B, the second ground layer GL2 includes a third body B3. The third body B3 may be connected to the ground.

Each of the above-described bodies B1, B2, and B3 shown in FIGS. 3B, 4B, and 6B may be made of an electrically conductive material, and each of the capacitance pattern and the first inductance pattern shown in FIG. 5B and the second inductance pattern shown in FIG. 3B may also be made of an electrically conductive material.

Referring to FIGS. 4B and 6B, each of the body B2 of the first ground layer GL1 and the body B3 of the second ground layer GL2 may include a third opening OP3, into which a shield can is inserted. Alternatively, the third opening OP3 may be omitted.

In addition, among the first to fifteenth vias VA1 to VA15, the vias except for the first, third, fifth, and sixth vias VA1, VA3, VAS, and VA6 may also serve to interconnect the second conductive pattern layer TL2, the first ground layer GL1, the first conductive pattern layer TL1, and the second ground layer GL2 in the vertical direction.

Each of the first to fifteenth vias VA1 to VA15 may be made of an electrically conductive material. In each of FIGS. 3B, 4B, and 5B, a portion having an annular planar shape is a conductive line area corresponding to the via.

The aforementioned electrically conductive material may be copper (Cu), but the disclosure is not limited to any specific material.

In addition, portions represented by a white background in FIGS. 3B, 4B, 5B, and 6B and the first and second openings OP1 and OP2 may be filled with a dielectric material (or a dielectric) EM. A dielectric material may also be charged between the second conductive pattern layer TL2 and the first ground layer GL1, between the first ground layer GL1 and the first conductive pattern layer TL1, and between the first conductive pattern layer TL1 and the second ground layer GL2.

As the line width of each of the above-described first to sixth inductor patterns LP1, LP2, LP3, LP4, LP5, and LP6 is reduced, the length thereof may be designed to be shorter. In consideration thereof, according to the embodiment, when the line width of each of the first to sixth inductor patterns LP1, LP2, LP3, LP4, LP5, and LP6 is greater than 250 μm, the efficiency of the inductor may decrease. Therefore, the line width of each of the first to sixth inductor patterns LP1, LP2, LP3, LP4, LP5, and LP6 may be 250 μm or less, but the disclosure is not limited thereto.

On the other hand, when the line width of each of the first and third capacitor patterns CP1 and CP3 is less than 300 μm, the efficiency of the capacitor may decrease. Therefore, according to the embodiment, the line width of each of the first and third capacitor patterns CP1 and CP3 may be 300 μm or greater, but the disclosure is not limited thereto.

The length of each of the first to sixth inductor patterns LP1, LP2, LP3, LP4, LP5, and LP6 may be equal to or less than one-eighth of the wavelength at a fundamental frequency (e.g. 2.4 GHz). Here, the fundamental frequency is a frequency at which insertion loss is zero.

For example, the length of each of the first to sixth inductor patterns LP1, LP2, LP3, LP4, LP5, and LP6 may be a length thereof defined between the vias. For example, referring to FIG. 3B, the length of the 3-1^{st} inductor pattern LP31 disposed between the first via VA1 and the fifth via VA5 may be equal to or less than one-eighth of the wavelength at the fundamental frequency, for example, 2.4 GHz, and the length of the 3-2^{nd} inductor pattern LP32 disposed between the fifth via VA5 and the sixth via VA6 may be equal to or less than one-eighth of the wavelength at the fundamental frequency, for example, 2.4 GHz. In addition, the length of each of the first and third capacitor patterns CP1 and CP3 in each of the x-axis direction and the y-axis direction may also be equal to or less than one-eighth of the wavelength at the fundamental frequency, for example, 2.4 GHz. For example, the length of each of the first to sixth inductor patterns LP1, LP2, LP3, LP4, LP5, and LP6 and the first and third capacitor patterns CP1 and CP3 may be 4.5 mm or less.

The area of each of the first to sixth inductor patterns LP1 to LP6 and the first to third capacitor patterns CP1, CP2, and CP3 depends on the length and line width thereof.

Hereinafter, operation of the filter module 10 or 10A according to the embodiment, which serves as the band-pass filter shown in FIG. 2 using the configuration shown in FIGS. 3A to 6B, will be described with reference to the accompanying drawings.

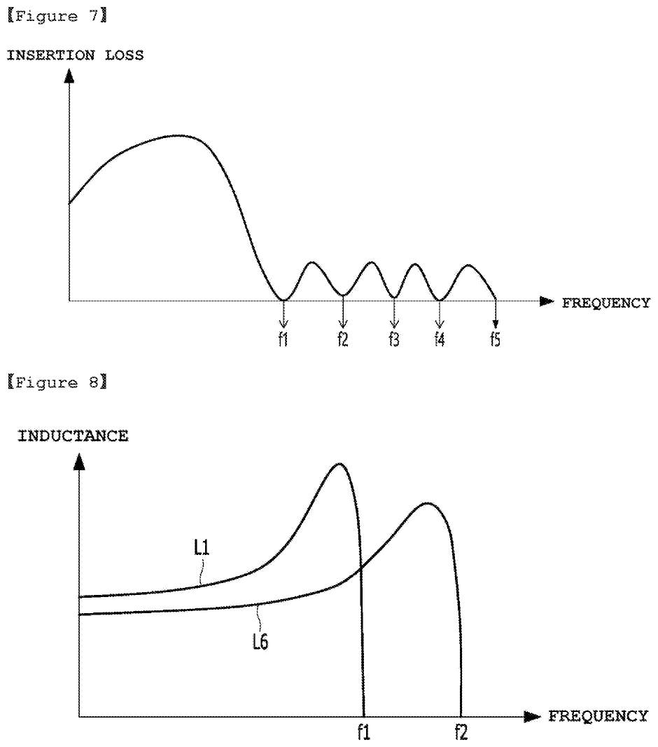

FIG. 7 is a graph showing insertion loss of the filter module 10A according to the embodiment at each frequency, in which the horizontal axis represents frequency, and the vertical axis represents insertion loss.

FIG. 8 is a graph showing inductance implemented by the first and sixth inductor patterns LP1 and LP6 at each frequency, in which the horizontal axis represents frequency, and the vertical axis represents inductance.

The line width and length of each of the first and sixth inductor patterns LP1 and LP6 may be adjusted such that the self-resonance frequency (SRF) of the first inductor pattern LP1 becomes f1, which is a second-order harmonic frequency of a Bluetooth antenna or a Wi-Fi signal (refer to FIG. 7), and such that the self-resonance frequency (SRF) of the sixth inductor pattern LP6 becomes f2, which is a second-order harmonic frequency of a Bluetooth antenna or a Wi-Fi signal (refer to FIG. 8). Here, when the fundamental frequency is 2.4 GHz, a transmission zero frequency f1 may be 4.8 GHz, and a transmission zero frequency f2 may be 5 GHz or 5.5 GHz. To this end, the line width may be 80 μm to 200 μm, and the length may be one-quarter of the wavelength at 4.8 GHz. A point at which the transfer functions of the first inductor L1, the second inductor L2, and the first capacitor C1 become zero corresponds to “f1” shown in FIGS. 7 and 8, and a point at which the transfer functions of the fifth inductor L5, the sixth inductor L6, and the third capacitor C3 become zero corresponds to “f2” shown in FIGS. 7 and 8.

In addition, the first and sixth inductors L1 and L6 may also serve to remove low-frequency noise such as a direct current component, and may also serve to perform impedance matching.

The second inductor L2 implemented by the second inductor pattern LP2 and the first capacitor C1 implemented by the first capacitor pattern CP1 generate a transmission zero at the resonance frequency. Similarly, the fifth inductor L5 implemented by the fifth inductor pattern LP5 and the third capacitor C3 implemented by the third capacitor pattern CP3 generate a transmission zero at the resonance frequency. The embodiment may be designed such that the resonance frequency is the second-order harmonic frequency of the Bluetooth antenna or the Wi-Fi antenna.

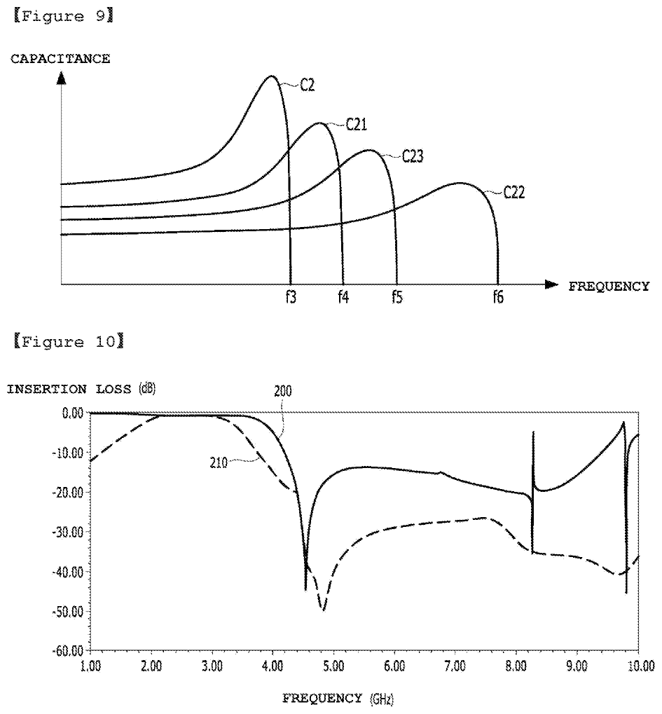

FIG. 9 is a graph showing capacitance of the second capacitor pattern CP2 at each frequency, in which the horizontal axis represents frequency, and the vertical axis represents capacitance.

The third inductor L3 implemented by the third inductor pattern LP3, the fourth inductor L4 implemented by the fourth inductor pattern LP4, and the second capacitor C2 implemented by the second capacitor pattern CP2 generate a transmission zero at the resonance frequency. The third inductor L3, the fourth inductor L4, and the second capacitor C2 may determine the bandwidth of the filter.

When the second capacitor C2 is designed as a parasitic component, there are two complete matching poles in a passband, and when the second capacitor C2 is designed as a resonator, there are three complete matching poles in a passband.

The second capacitor C2 may have a configuration composed of three band stubs. Referring to FIG. 9, the second capacitor C2 may be implemented so as to have a transmission zero at a frequency f3 by combining a 2-1^{st} capacitor C21 implemented by the first stub CP21, a 2-2^{nd} capacitor C22 implemented by the second stub CP22, and a 2-3^{rd} capacitor C23 implemented by the third stub CP23. In FIG. 9, the resonance point f4 of the 2-1^{st} capacitor C21 may be 9.6 GHz, the resonance point f5 of the 2-3^{rd} capacitor C23 may be 12 GHz, the resonance point f6 of the 2-2^{nd} capacitor C22 may be 14.4 GHz, and the overall resonance point f3 of the second capacitor C2 may be 7.2 GHz.

The second capacitor C2 may have a configuration in which three resonators are combined, and may be designed such that the self-resonance frequency thereof falls within a harmonic frequency of 2.4 GHz to 2.5 GHz. A plurality of resonators may be combined as needed.

Hereinafter, a filter module according to a comparative example and the filter module according to the embodiment will be described with reference to the accompanying drawings.

FIG. 10 is a graph showing insertion loss 200 of a filter module according to a comparative example and insertion loss 210 of the filter module according to the embodiment, in which the horizontal axis represents frequency, and the vertical axis represents insertion loss.

Referring to FIG. 10, the filter module 210 according to the embodiment has a passband of 2.4 GHz to 2.5 GHz, and the bandwidth of 3 dB is 2.2 GHz to 3.2 GHz.

The filter module 200 of the comparative example constitutes a band-pass filter using a capacitor or an inductor, which is a lumped element. Referring to FIG. 10, it can be seen that the embodiment 210 exhibits excellent isolation effects of at least −30 dB in a harmonic wave generation section greater than 4.8 GHz compared to the comparative example 200.

In the embodiment, since each of the first, second, third, fifth, and sixth inductor patterns LP1, LP2, LP3, LP5, and LP6 is formed so as to be bent at least once in the horizontal direction, a sufficient length thereof may be secured in a limited space, and accordingly, each of the inductors L1, L2, L3, L5, and L6 may be designed to include a desired inductance.

In addition, the filter module 10 or 10A according to the embodiment may reduce harmonic components other than raw signals caused by an oscillator (not shown) and a mixer (not shown) in an IC.

In addition, the filter module 10 or 10A according to the embodiment may improve impedance matching with respect to a transmission line by controlling a pole point, thereby reducing insertion loss. That is, since impedance matching is improved when an antenna or an element is connected to the first port P1 and the second port P2, the efficiency of the antenna may be improved, and consequently, a transmission distance and a transmission rate may increase.

The filter module of the comparative example constitutes a band-pass filter using a capacitor or an inductor, which is a lumped element, and is provided with a separate transmission line, thus causing large insertion loss. In contrast, according to the embodiment, since the band-pass filter is constituted by the inductors L3 and L4 implemented using the transmission lines, the wavelength may be shortened, and thus group delay may be improved. Accordingly, a signal distortion rate may be reduced.

Consequently, in the filter module 10 or 10A according to the embodiment, the second conductive pattern layer TL2 is designed to be combined with the transmission line, thereby minimizing signal distortion. Further, since components for blocking harmonic components are located between the first ground layer GL1 and the second ground layer GL2 in a state of being shielded, noise may be easily removed through ground without being radiated. That is, since the embodiment is designed such that a signal having a main frequency of 2.4 GHz to 2.5 GHz is directly connected to an existing transmission line, impedance matching may be improved, insertion loss may be reduced, and signal distortion may be minimized. Further, a blocked signal may be caused to flow to the ground, whereby reintroduction or radiation thereof may be prevented.

The filter module according to the embodiment may be modularized and may be applied to communication devices or filters for communication devices such as, for example, organic light-emitting diode (OLED) TVs, Wi-Fi/BT combination modules, multi-antenna systems, and repeaters for LTE/Wi-Fi 5G and 6G.

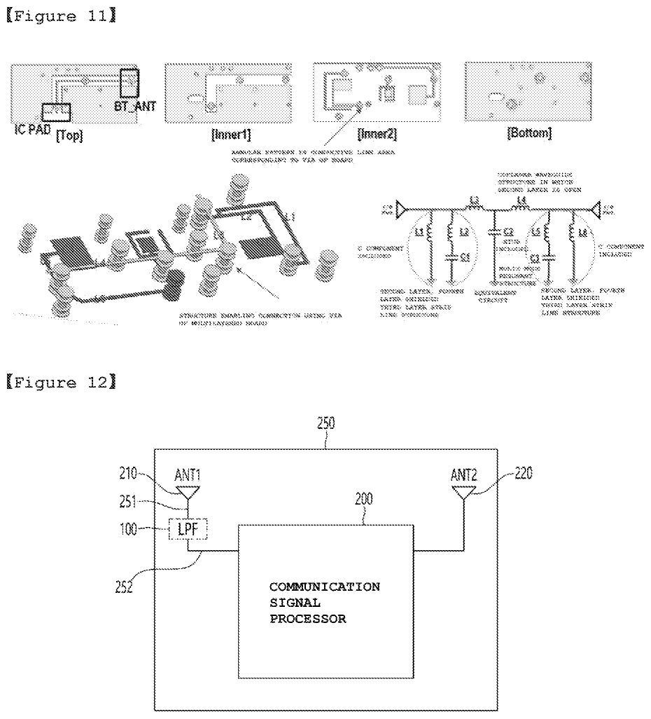

FIG. 11 is a diagram illustrating the connection structure of the filter module according to the embodiment in order to aid in understanding of the embodiment. Although already described above, the conductive pattern connection structure is illustrated in FIG. 11 in order to aid in understanding thereof.

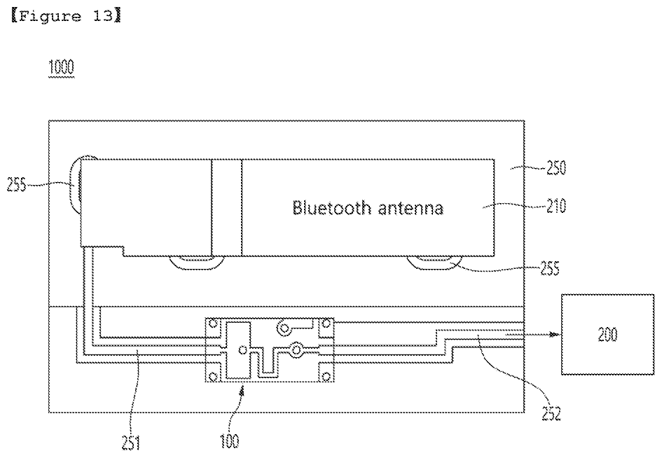

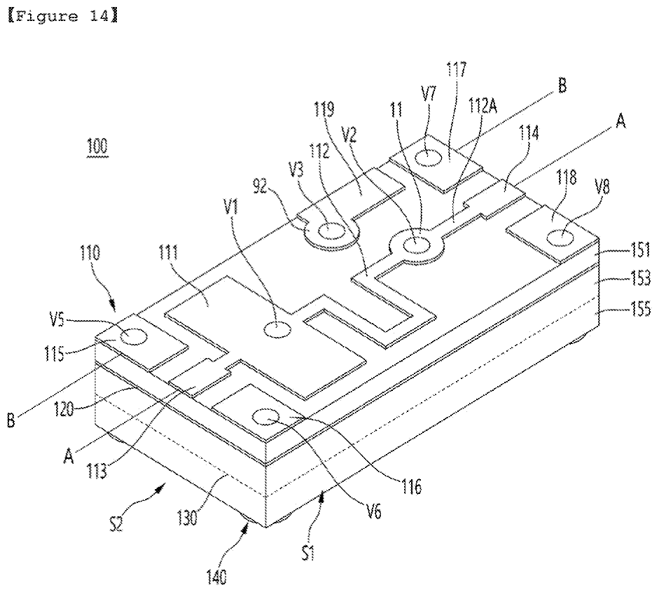

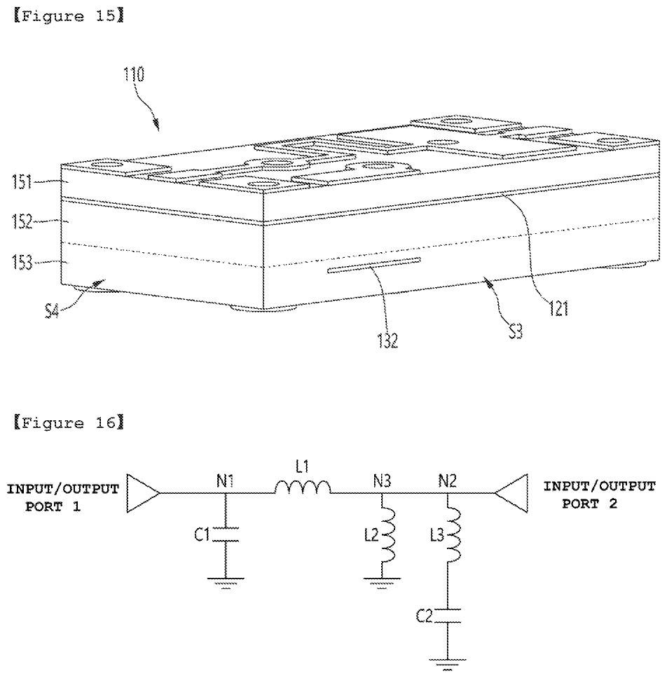

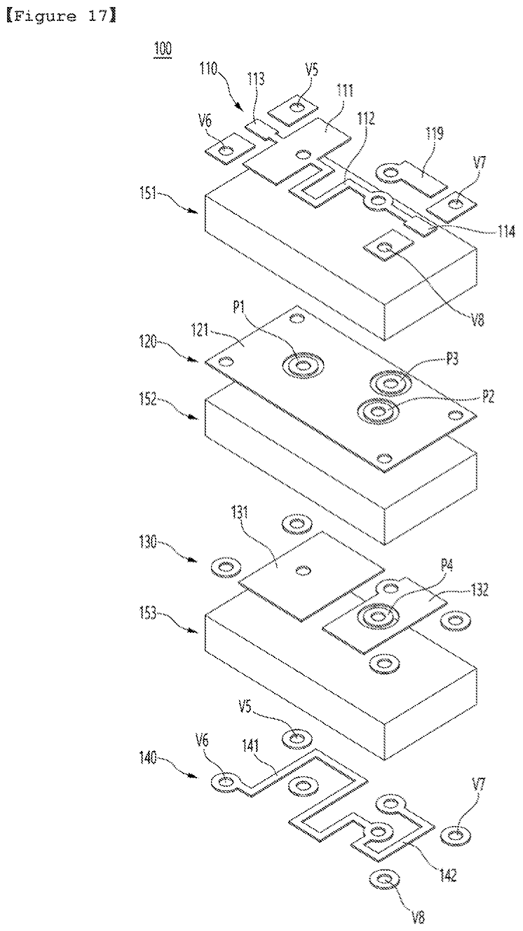

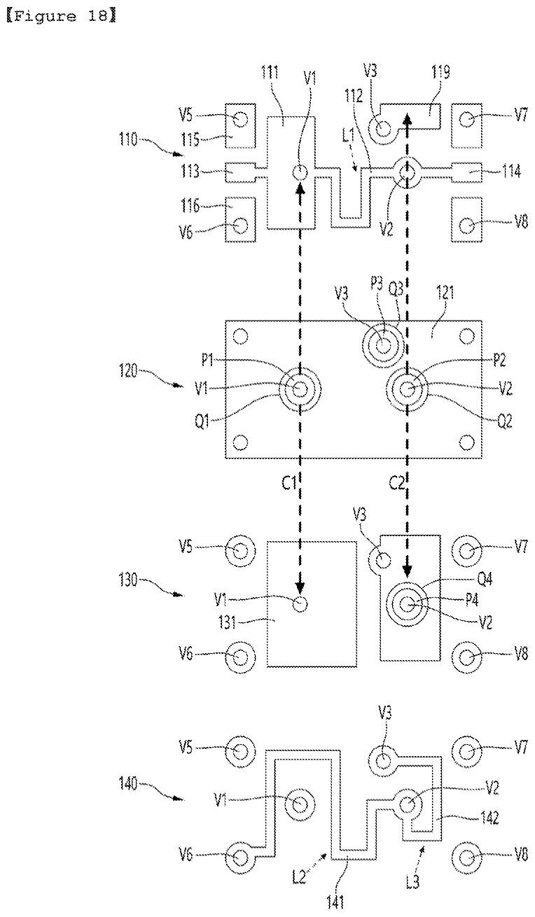

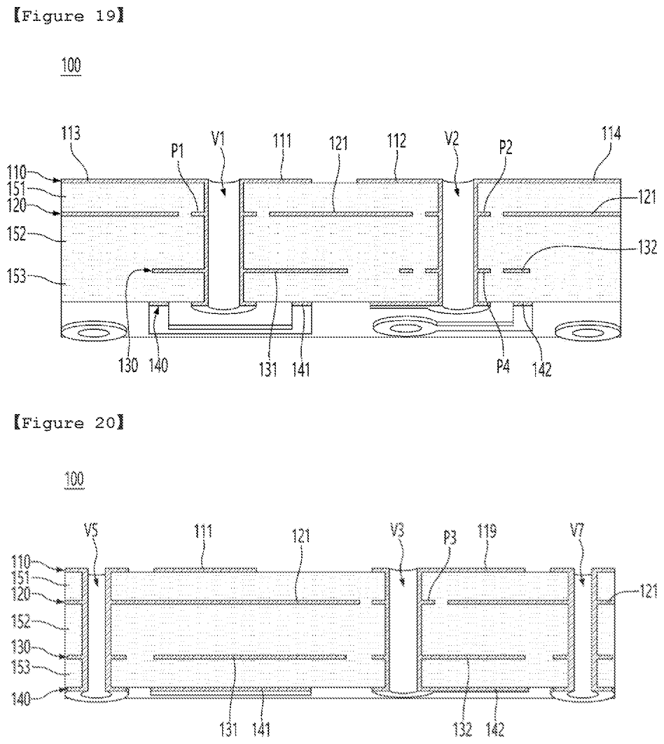

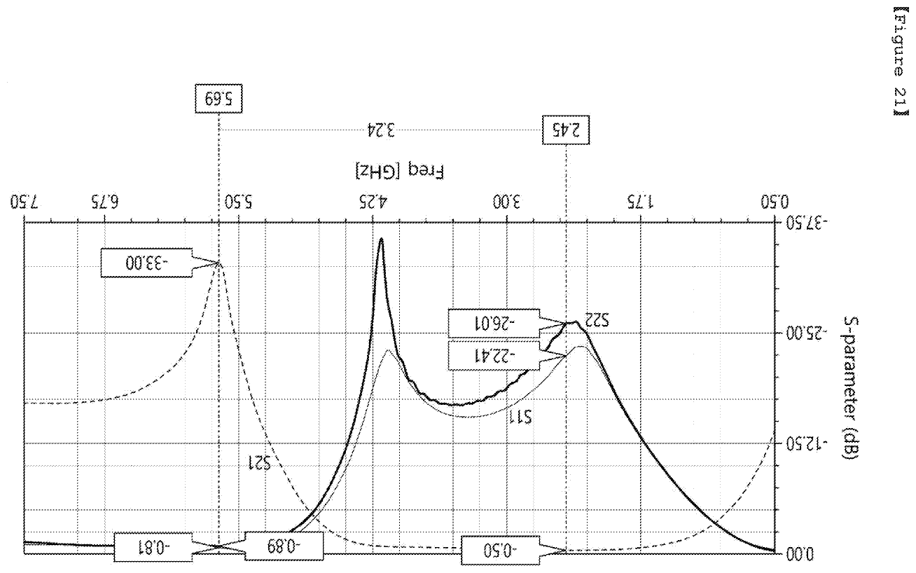

FIG. 12 is a block configuration diagram of an antenna module according to an embodiment of the present disclosure. FIG. 13 is a plan view showing a part of the antenna module shown in FIG. 12. FIG. 14 is a perspective view of the low-pass filter unit shown in FIG. 13. FIG. 15 is a side view of the low-pass filter unit shown in FIG. 14. FIG. 16 is a diagram showing the circuit configuration of the low-pass filter according to the present disclosure. FIG. 17 is an exploded perspective view of the low-pass filter unit shown in FIG. 14. FIG. 18 is a view showing patterns of first to fourth conductive layers of the low-pass filter unit shown in FIG. 17. FIG. 19 is a cross-sectional view taken along line A-A in the low-pass filter unit shown in FIG. 14. FIG. 20 is a cross-sectional view taken along line B-B in the low-pass filter unit shown in FIG. 14. FIG. 21 is a graph showing the operational characteristics of the low-pass filter unit of the antenna module according to the embodiment of the present disclosure.

Referring to FIG. 12, the antenna module includes a first antenna 210 configured to transmit and receive a first high-frequency signal, a low-pass filter unit 100 connected to transmission lines 251 and 252 of the first antenna 210, a second antenna 220 configured to transmit and receive a second high-frequency signal, and a communication signal processor 200 configured to generate and process transmitted/received signals of the first and second antennas 210 and 220.

The first antenna 210 may be implemented as a Bluetooth antenna, the second antenna 220 may be implemented as a Wi-Fi antenna, and the communication signal processor 200 may be implemented as a Wi-Fi module.

The first high-frequency signal includes a Bluetooth signal, for example, a band of 2402 to 2480 MHz. The second high-frequency signal includes a Wi-Fi signal, for example, a band of 2400 to 2483 MHz and a band of 5 to 6 GHz. Here, the first high-frequency signal uses a channel overlapping the low frequency band (e.g. 2402 to 2480 MHz) of the second high-frequency signal, but does not use a channel overlapping the high frequency band (e.g. 5 to 6 GHz) of the second high-frequency signal.

As shown in FIGS. 13 to 15, the low-pass filter unit 100 may be connected to the transmission lines 251 and 252 between the first antenna 210 and the communication signal processor 200. The low-pass filter unit 100 may pass a low frequency band and may filter a high frequency band. The low-pass filter unit 100 may be connected between the first transmission line 251 connected to the first antenna 210 and the second transmission line 252 connected to the communication signal processor 200. The first and second transmission lines 251 and 252 are feed lines for feeding signals.

The low-pass filter unit 100 may form a resonance circuit using an inductor and a capacitor, and the inductor and the capacitor may be implemented patterns of conductive layers and dielectric layers, rather than by passive components. In this way, since no passive component is used, cost of manufacturing the low-pass filter unit 100 and the size thereof may be reduced.

The first and second antennas 210 and 220 may be coupled to a board 250. The first antenna 210 may be coupled to coupling portions 255 of the board 250, and the coupling portions 255 may be coupling holes into which lower coupling protrusions of the first antenna 210 are fitted. Any one of the coupling portions 255 of the board 250 may be connected to the first transmission line 251. The low-pass filter unit 100 may be embedded in the board 250 of the communication signal processor 200. The board 250 may be a multilayered board including a plurality of conductive layers.

As shown in FIG. 16, the circuit configuration of the low-pass filter unit 100 is implemented as a passive filter including a first input/output port and a second input/output port configured to transmit and receive signals. One end of the first capacitor C1 is connected in parallel to a first branch node N1 connected to the first input/output port, and the other end of the first capacitor C1 is grounded. One end of the first inductor L1 is connected to the first branch node N1 in series, and a third branch node N3 is connected to the other end of the first One end of the second inductor L2 is connected in parallel to the third branch node N3, and the other end of the second inductor L2 is grounded.

One end of the third inductor L3 is connected in parallel to a second branch node N2 connected to the second input/output port, one end of the second capacitor C2 is connected to the other end of the third inductor L3 in series, and the other end of the second capacitor C2 is grounded. The second branch node N2 is connected to the third branch node N3 in series.

The first input/output port may be connected to or integrally formed with the first transmission line 251. The second input/output port may be connected to or integrally formed with the second transmission line 252. The low-pass filter unit 100 passes a first frequency band (e.g. 2400 to 2483 MHz) transmitted to the first and second input/output ports, and filters a second frequency band (e.g. 5 to 6 GHz).

The first to third inductors L1, L2, and L3 may include different inductances in the range of 0.5 to 4 nH. For example, the first inductor L1 may include an inductance of 1.3 nH±0.2 nH, the second inductor L2 may include an inductance of 2.7 nH±0.2 nH, and the third inductor L3 may include an inductance of 1.5 nH±0.2 nH. The first and second capacitors C1 and C2 may include different capacitances in the range of 0.3 to 2.5 pF. For example, the first capacitor C1 may include a capacitance of 0.9 pF±0.05 pF, and the second capacitor C2 may include a capacitance of 0.5 pF±0.01 pF.

As shown in FIGS. 14, 15, and 17 to 20, the low-pass filter unit 100 may be part of the board 250 shown in FIG. 13, or may be a board area embedded in the board 250.

The low-pass filter unit 100 may include a plurality of conductive layers 110, 120, 130, and 140 and a plurality of dielectric layers 151, 152, and 153 respectively disposed between the plurality of conductive layers 110, 120, 130, and 140. Each of the plurality of conductive layers 110, 120, 130, and 140 may be made of copper, or may include a copper layer and at least one plating layer stacked on the surface of the copper layer. The plating layer may include at least one of nickel, gold, tin, lead, palladium, silver, or mixtures thereof.

The dielectric layers 151, 152, and 153 may include an insulating material, for example, at least one of FR-4, CEM-1, RF-35, Teflon, polyimide, or polytetrafluoroethylene (PTFE). The dielectric layers 151, 152, and 153 may include a dielectric of a capacitor, such as Ta2O5, BaO4SrTi, TiO2, BaO, A12O3, PbO, CaO, or B2O3.

The plurality of conductive layers 110, 120, 130, and 140 may include first to fourth conductive layers 110, 120, 130, and 140 stacked in a direction from the upper surface of the board 250 toward the lower surface of the board 250. The plurality of dielectric layers 151, 152, and 153 may include first to third dielectric layers 151, 152, and 153 respectively disposed between the first to fourth conductive layers 110, 120, 130, and 140. The first and second dielectric layers 151 and 152 may include the aforementioned dielectric of the capacitor, and the thickness of the second dielectric layer 152 may be greater than that of the first dielectric layer 151. For example, the first and third dielectric layers 151 and 153 may be formed to have a thickness of 300 μm or less, for example, 100 to 300 μm, and the second dielectric layer 152 may be formed to have a thickness of 300 μm or greater, for example, 300 to 500 μm.

The first dielectric layer 151 is disposed between the first conductive layer 110 and the second conductive layer 120, the second dielectric layer 152 is disposed between the second conductive layer 120 and the third conductive layer 130, and the third dielectric layer 153 is disposed between the third conductive layer 130 and the fourth conductive layer 140. The first conductive layer 110 may be exposed on the upper surface of the board, and the fourth conductive layer 140 may be exposed on the lower surface of the board.

As shown in FIGS. 14 and 15, the low-pass filter unit 100 may be formed such that the width between a first side S1 thereof and a third side S3 thereof is less than the length between a second side surface S2 thereof and a fourth side surface S4 thereof. Accordingly, a long conductive pattern of the inductor may be disposed so as to extend in a first direction (longitudinal direction) from the second side surface S2 toward the fourth side surface S4. In addition, a short conductive pattern of the inductor may be disposed so as to extend in a second direction (width direction) from the first side surface S1 toward the third side surface S3. The first conductive layer 110 may be exposed on the upper surface of the board, and the fourth conductive layer 140 may be exposed on the lower surface of the board. As shown in FIG. 15, a portion of the pattern 132 of the second conductive layer 140 may be exposed on the third side surface S3.

As shown in FIGS. 15 and 17, the first conductive layer 110 may include a first pattern 111, a second pattern 112, and a third pattern 119, the second conductive layer 120 may include a ground pattern 121, the third conductive layer 130 may include a fourth pattern 131 and a fifth pattern 132, which are spaced apart from each other, and the fourth conductive layer 140 may include a sixth pattern 141 and a seventh pattern 142, which are connected to each other via the second via V2.

The first pattern 111 and the second pattern 112 of the first conductive layer 110 are connected to the first via V1 the second via V2, which are spaced apart from each other in the first direction. The first pattern 111 is a polygonal plate-shaped pattern, and the second pattern 112 is a line-shaped pattern, which has a smaller width than the plate-shaped pattern. The first pattern 111 includes therein the first via V1 and is connected to one end of the second pattern 112, and the other end of the second pattern 112 is connected to the second via V2. The second pattern 112 has a bent structure, e.g. a structure bent twice or more or three times or more. The second pattern 112 may increase or reduce a value of the inductance depending on the bent shape and length thereof. The second pattern 112 (L1) may have a length of 0.5 to 3 mm. Here, the length of the second pattern 112 (L1) is a length extending from one end thereof to the other end thereof. The second pattern 112 (L1) may have a width of 10 to 200 μm.

The first pattern 111 is connected at one end thereof to the second pattern 112 and is connected at the other end thereof to a first input/output pattern 113, and the second pattern 112 and the second via V2 are connected to a second input/output pattern 114. The first and second input/output patterns 113 and 114 are the first and second input/output ports. The second via V2 may include a circular pattern on the periphery thereof, and the diameter of the circular pattern may be greater than the width of the second pattern 112.

The third pattern 119 may be a plate-shaped pattern including the third via V3, and may be spaced apart from the first and second patterns 111 and 112. The third pattern 119 may have a polygonal shape. The third via V3 may include a hemispherical pattern formed on one side of the periphery thereof. The area of the upper surface of the third pattern 119 may be smaller than the area of the upper surface of the first pattern 111. The third via V3 may be disposed between the fifth via V5 and the seventh via V7 in the first direction, and may be located closer to the seventh via V7 than to the fifth via V5.

Patterns 115, 116, 117, and 118 including the fifth to eighth vias V5 to V8 are disposed on respective corners of the first conductive layer 110, and are physically spaced apart from the first to third patterns 111, 112, and 119. In the first conductive layer 110, the patterns 115, 116, 117, and 118 including the fifth to eighth vias V5 to V8 may have a polygonal shape.

As shown in FIGS. 17 and 18, the second conductive layer 120 includes a ground pattern 121. The ground pattern 121 is provided with a first circular pattern P1 connected to the first via V1, a second circular pattern P2 connected to the second via V2, and a third circular pattern P3 connected to the third via V3.

The first to third circular patterns P1, P2, and P3 may be spaced apart from the ground pattern 121 by predetermined gaps Q1, Q2, and Q3, respectively. Each of the first to third circular patterns P1, P2, and P3 is not physically connected to the ground pattern 121.

The ground pattern 121 is connected to the fifth to eighth vias V5 to V8. The area of the upper surface of the ground pattern 121 may be larger than the areas of the upper surfaces of the patterns of the first conductive layer 110, or may be larger than the areas of the upper surfaces of the patterns of the third conductive layer 130.

The third conductive layer 130 includes a fourth pattern 131 connected to the first via V1 and a fifth pattern 132 connected to the second via V2 and the third via V3. The fourth pattern 131 and the first pattern 111 of the first conductive layer 110 face each other, with the ground pattern 121 interposed therebetween. The area of the upper surface of the fourth pattern 131 may be larger than the area of the upper surface of the first pattern 111.

The second via V2 disposed in the fifth pattern 132 may include a fourth circular pattern P4, and the fourth circular pattern P4 may be spaced apart from the fifth pattern 132 by a predetermined gap Q4. The fourth circular pattern P4 is not physically connected to the fifth pattern 132. The fifth pattern 132 may be connected at an inner side thereof to the third pattern 119. The fifth pattern 132 and the second and third patterns 112 and 119 face each other, with the ground pattern 121 interposed therebetween.

The fourth pattern 131 and the fifth pattern 132 may be implemented as a polygonal plate-shaped pattern. The area of the upper surface of the fourth pattern 131 may be larger than the area of the upper surface of the first pattern 111, and may be larger than the area of the upper surface of the fifth pattern 132. In addition, the area of the upper surface of the fifth pattern 132 may be larger than the area of the upper surface of the first pattern 111. Here, the polygonal shape may include a quadrangular shape.

The fifth to eighth vias V5 to V8 may be disposed on respective corners of the third conductive layer 130. The fifth to eighth vias V5 to V8 of the third conductive layer 130 may include circular patterns. As shown in FIGS. 19 and 20, the gaps Q1, Q2, Q3, and Q4 may be filled with the materials of the dielectric layers.

The fourth conductive layer 140 includes a sixth pattern 141 and a seventh pattern 142. The sixth pattern 141 and the seventh pattern 142 are connected to each other via the second via V2. The sixth pattern 141 is a line pattern, which extends between the second via V2 and the sixth via V6. The sixth pattern 141 may be formed in a line shape having a structure bent twice or more. For example, the sixth pattern 141 may be formed in a line shape having a structure bent four times or more.

The overall length of the sixth pattern 141 may be greater than the overall length of the second pattern 112. The number of bends of the sixth pattern 141 may be greater than the number of bends of the second pattern 112 by, for example, two or greater. The sixth pattern 141 (L2) has a length (overall length) of 3 to 10 mm. The sixth pattern 141 (L2) has a width of 10 to 200 μm.

The seventh pattern 142 is a line pattern, which is connected between the second via V2 and the third via V3. The seventh pattern 142 may be formed in a line shape having a structure bent once or more. For example, the seventh pattern 142 may be formed in a line shape having a structure bent twice or three times or more. The seventh pattern 142 (L3) has a length (overall length) of 0.5 to 3 mm. The seventh pattern 142 (L3) has a width of 10 to 200 μm.

The fifth to eighth vias V5 to V8 may be disposed on respective corners of the fourth conductive layer 140. The fifth to eighth vias V5 to V8 of the fourth conductive layer 140 may include circular patterns.

Here, the first capacitor C1 may include a first capacitance, which is generated by the first dielectric layer 151 between the first pattern 111 of the first conductive layer 110 and the first circular pattern P1 of the second conductive layer 120, and a second capacitance, which is generated by the second dielectric layer 152 between the first circular pattern P1 and the fourth pattern 131. The first pattern 111 of the first conductive layer 110 and the fourth pattern 131 of the third conductive layer 130 may function as both electrode terminals of the first capacitor. The first and second capacitances may be connected to each other in series.

Here, the first inductor L1 is implemented as the second pattern 112 connected between the first pattern 111 and the second via V2. The inductance value of the first inductor L1 may vary depending on the length and/or area of the second pattern 112. Each of the second pattern 112, the sixth pattern 116, and the seventh pattern 117 may be a line pattern for an inductor.

The second inductor L2 is implemented as the line-shaped sixth pattern 141 connected between the second via V2 and the sixth via V6 of the fourth conductive layer 140. The inductance value of the second inductor L2 may vary depending on the length and/or area of the sixth pattern 141. The second inductor L2 may be connected to the ground pattern 121 via the sixth via V6. The inductance value of the sixth pattern 141 may be greater than that of the second pattern 112.

The third inductor L3 is implemented as the line-shaped seventh pattern 142 connected between the second via V2 and the third via V3. The inductance value of the third inductor L3 may vary depending on the length and/or area of the seventh pattern 142. The inductance value of the seventh pattern 142 may be greater than that of the second pattern 112.

The second capacitor C2 may be formed so as to be connected to the fifth pattern 132, the third circular pattern P3, and the third pattern 119 via the third via V3 connected to the seventh pattern 142. In this case, the second capacitor C2 may include a third capacitance, which is generated by the first dielectric layer 151 between the third pattern 119 and the third circular pattern P3, and a fourth capacitance, which is generated by the second dielectric layer 152 between the third circular pattern P3 and the fifth pattern 132. In addition, the second capacitor C2 may include a fifth capacitance, which is generated by the first dielectric layer 151 between the second via V2 and the second circular pattern P2, and a sixth capacitance, which is generated by the second dielectric layer 152 between the second circular pattern P2 and the fourth circular pattern P4. The third and fourth capacitances may be connected to each other in series, and the fifth and sixth capacitances may be connected to each other in series. The third and fifth capacitances may be connected in parallel to each other, and the fourth and sixth capacitances may be connected in parallel to each other. Accordingly, the second capacitor C2 may include the third to sixth capacitances due to the patterns of the first and second dielectric layers 151 and 152, and may be connected to the seventh pattern 142 in series.

Since the first pattern 111 has a larger area than the third pattern 119 and the fourth pattern 131 has a larger area than the fifth pattern 132, the capacitance value of the second capacitor C2 may be smaller than that of the first capacitor C1.

As shown in FIG. 19, the first pattern 111, the first circular pattern P1, and the fourth pattern 131 are connected to the first via V1, and the second pattern 112, the second circular pattern P2, the fourth circular pattern P4, and the sixth pattern 141 are connected to the second via V2.

As shown in FIG. 20, the third pattern 119, the third circular pattern P3, the fifth pattern 132, and the seventh pattern 142 are connected to the third via V3. The fifth via V5 is connected to the ground pattern 121, and is connected to the via patterns of the first, third, and fourth conductive layers 110, 130, and 140. The fifth via V5 may not be connected to the via patterns of the third and fourth conductive layers 130 and 140. That is, the fifth, seventh, and eighth vias V5, V7, and V8 of the third and fourth conductive layers may be patterns disposed to support the portion between two dielectric layers. The seventh via V7 is connected to the ground pattern 121, and is connected to the via patterns of the first, third, and fourth conductive layers 110, 130, and 140.

The first to third branch nodes N1, N2, and N3 may be formed by the first to third vias V1, V2, and V3 disposed in the low-pass filter unit 100, respectively.

As another example of the present disclosure, the disposition positions of the conductive layers and the dielectric layers may be set to be opposite those shown in FIG. 17. For example, the patterns of the first conductive layer 110 may be disposed on the fourth conductive layer, the patterns of the second conductive layer 110 may be disposed on the third conductive layer, the patterns of the third conductive layer 130 may be disposed on the second conductive layer, and the patterns of the fourth conductive layer 140 may be disposed on the first conductive layer. That is, the patterns of the respective layers may be implemented by embedding the structure shown in FIG. 17 in the board in a state of vertically inverting the same or rotating the same 180 degrees. In this case, the input/output patterns may be disposed on the fourth conductive layer 140, and may be connected to the transmission lines 251 and 252 via the lower surface of the board 250.

The low-pass filter unit 100 embedded in the board as described above may have frequency response characteristics shown in FIG. 21. In the S-parameter, “S21” represents the insertion loss of the low-pass filter, which indicates comparison between the magnitude of a signal of the first input/output port and the magnitude of a signal output to the second input/output port. It can be seen that the insertion loss is equal to or less than −3 dB in a band of 5 to 6 GHz. That is, the low-pass filter unit 100 exhibits excellent filtering effects in a band of 5 to 6 GHz. As the insertion loss approaches 0, a signal flows more smoothly. In the S-parameter, “S11” represents a reflection coefficient or return loss at the first input/output port, and “S22” represents a reflection coefficient or return loss at the second input/output port. The frequencies of the transmission zeros (−22.41 and −26.01) in the curves S11 and S22 may be adjusted. The transmission zero at 4.25 GHz may be adjusted to be lower than the transmission zero at 2.45 GHz. A portion of the input power may be transmitted in a band of 5 GHz or more so that it may be set as a value for controlling the bandwidth and suppressing frequency.

The antenna module according to the embodiment of the present disclosure is a Wi-Fi module including Bluetooth and Wi-Fi antennas, and may be applied to high-frequency modules for mobile phones, TVs configured to receive high-frequency signals, vehicles, and the like.

### Mode for Invention

The mode for invention has be described in the above best mode.

### INDUSTRIAL APPLICABILITY

The filter module according to the embodiment may be applied to a field such as a Wi-Fi module including Bluetooth and Wi-Fi antennas, and to high-frequency modules for mobile phones, TVs configured to receive high-frequency signals, vehicles, and the like.

1.-15. (canceled)

16. A filter module, comprising:
a first ground layer;
a second ground layer disposed so as to be spaced apart from the first ground layer;
a first conductive pattern layer disposed between the first ground layer and the second ground layer;
a second conductive pattern layer disposed on one side of the first ground layer or the second ground layer; and
a via interconnecting at least two of the first ground layer, the second ground layer, the first conductive pattern layer, and the second conductive pattern layer.

17. The filter module according to claim 16, wherein the first conductive pattern layer includes a capacitance pattern formed to have a capacitance while facing at least one of the first ground layer or the second ground layer.

18. The filter module according to claim 17, wherein the first conductive pattern layer includes a first inductance pattern formed to have an inductance.

19. The filter module according to claim 17, wherein the second conductive pattern layer includes a second inductance pattern formed to have an inductance.

20. The filter module according to claim 19, wherein the inductance pattern has a smaller width than the capacitance pattern.

21. The filter module according to claim 20, wherein the second conductive pattern layer includes a first opening formed therein to allow the second inductance pattern to be disposed therein, and
wherein the first ground layer includes a second opening formed therein so as to vertically overlap the first opening.

22. The filter module according to claim 20, wherein each of the first inductance pattern and the second inductance pattern includes an inductance pattern having a planar shape bent at least once in a horizontal direction, and
wherein a maximum number of bends of the first inductance pattern in the horizontal direction is greater than a maximum number of bends of the second inductance pattern.

23. The filter module according to claim 20, wherein the capacitance pattern includes:
a second capacitor pattern forming a second capacitor;
a first capacitor pattern disposed so as to be spaced apart from one side of the second capacitor pattern to form a first capacitor; and
a third capacitor pattern disposed so as to be spaced apart from an opposite side of the second capacitor pattern to form a third capacitor.

24. The filter module according to claim 23, wherein the second capacitor pattern includes:
a first stub;
a second stub disposed on one side of the first stub; and
a third stub disposed on an opposite side of the first stub.

25. The filter module according to claim 23, wherein the first inductance pattern includes:
a first inductor pattern disposed so as to interconnect a first via and a second via to form a first inductor;
a second inductor pattern disposed so as to interconnect the first via and the first capacitor pattern to form a second inductor;
a fifth inductor pattern disposed so as to interconnect a third via and the third capacitor pattern to form a fifth inductor; and
a sixth inductor pattern disposed so as to interconnect the third via and a fourth via to form a sixth inductor.

26. The filter module according to claim 20, wherein the second inductance pattern includes:
a third inductor pattern disposed so as to interconnect a first via and a fifth via and interconnect the fifth via and a sixth via to form a third inductor; and
a fourth inductor pattern disposed so as to interconnect the sixth via and the third via to form a fourth inductor, and
wherein the sixth via is connected to the second capacitor pattern.

27. The filter module according to claim 26, wherein at least one of the first to sixth inductor patterns has a line width of 250 μm or less.

28. The filter module according to claim 23, wherein at least one of the first capacitor pattern or the third capacitor pattern has a line width of 300 μm or greater.

29. The filter module according to claim 26, wherein at least one of the first to sixth inductor patterns has a length equal to or less than one-eighth of a wavelength at a fundamental frequency.

30. A filter module, comprising:
a second ground layer;
a first conductive pattern layer stacked on the second ground layer, the first conductive pattern layer including a pattern implementing an inductor and a capacitor;
a first ground layer stacked on the first conductive pattern layer;
a second conductive pattern layer stacked on the first ground layer, the second conductive pattern layer including a transmission line including a pattern implementing an inductor; and
a via interconnecting the inductor and the capacitor of the first conductive pattern layer and the inductor of the second conductive pattern layer in a vertical direction.

31. An antenna module, comprising:
a board to which a first antenna is coupled;
a low-pass filter unit embedded in a portion of the board; and
a first transmission line interconnecting the first antenna and the low-pass filter unit,
wherein the low-pass filter unit includes first to fourth conductive layers and first to third dielectric layers respectively disposed between the first to fourth conductive layers,
wherein the first conductive layer includes a first pattern including a first via, a second pattern connected between one end of the first pattern and a second via, and a third pattern connected to a third via,
wherein the second conductive layer includes a ground pattern spaced apart from the first to third vias formed therein by predetermined gaps,
wherein the third conductive layer includes a fourth pattern facing the first pattern and a fifth pattern spaced apart from the fourth pattern and facing the second via and the third pattern,
wherein the fourth conductive layer includes a sixth pattern connected between the second via and a ground via formed therein and a seventh pattern connected between the second via and the third via,
wherein the first pattern and the third pattern of the first conductive layer, the fourth pattern and the fifth pattern of the third conductive layer, and the first and second dielectric layers form first and second capacitors, and
wherein the second pattern, the sixth pattern, and the seventh pattern have a line shape and form first to third inductors.

32. The antenna module according to claim 31, wherein the first pattern and the third pattern of the first conductive layer and the fourth pattern and the fifth pattern of the third conductive layer have a polygonal plate shape.

33. The antenna module according to claim 31, wherein an area of an upper surface of the fifth pattern is smaller than an area of an upper surface of the third pattern, and is larger than an area of an upper surface of the first pattern.

34. The antenna module according to claim 31, wherein an area of an upper surface of the third pattern is smaller than an area of an upper surface of the first pattern.

35. The antenna module according to claim 31, wherein the first conductive layer comprises:
a first input/output pattern connected to an other end of the first pattern and the first transmission line; and
a second input/output pattern connected to the second pattern and a second transmission line disposed on the opposite side of the low-pass filter unit.
